(19) United States
(12) Patent Application Publication
(10) Pub. No.: US 2023/0024466 A1
(43) Pub. Date: Jan. 26, 2023

(54) FILM PIEZOELECTRIC ACOUSTIC RESONATOR, FILTER AND ELECTRONIC APPARATUS

(71) Applicant: Ningbo Semiconductor International Corporation, Ningbo (CN)

(72) Inventors: Herb He HUANG, Ningbo (CN); Hailong LUO, Ningbo (CN); Wei LI, Ningbo (CN)

(21) Appl. No.: 17/941,930

(22) Filed: Sep. 9, 2022

Related U.S. Application Data
(63) Continuation of application No. PCT/CN2020/137047, filed on Dec. 17, 2020.

(30) Foreign Application Priority Data
Mar. 10, 2020 (CN) 202010162461.4

(51) Int. Cl. H03H 9/17; H03H 9/02; H03H 9/54

(52) U.S. Cl. CPC H03H 9/172; H03H 9/02015; H03H 9/54

(57) ABSTRACT

The present disclosure provides a film piezoelectric acoustic resonator. The resonator includes an upper electrode, a piezoelectric layer and a lower electrode which are stacked sequentially from a top to a bottom. A projection of the effective resonance region along a direction of the piezoelectric layer is a hexagon. The hexagon has a first side with a longest length, a second side opposite to the first side, a third side with a shortest length, and a fourth side opposite to the third side. A portion of the upper electrode extending out of the effective resonance region through a first boundary of the effective resonance region is defined as an upper electrode led-out portion; a portion of the lower electrode extending out of the effective resonance region through a second boundary of the effective resonance region is defined as a lower electrode led-out portion.

### CROSS-REFERENCE TO RELATED APPLICATION

This application is a continuation application of PCT Patent Application No. PCT/CN2020/137047, filed on Dec. 17, 2020, which claims priority to Chinese patent application No. 202010162461.4, filed on Mar. 10, 2020, the entirety of all of which is incorporated herein by reference.

### FIELD OF THE DISCLOSURE

The present disclosure generally relates to the field of semiconductor device manufacturing, and more particularly, relates to a film piezoelectric acoustic resonator, a filter and an electronic apparatus.

### BACKGROUND

Since the analog radio frequency (RF) communication technology is developed in early 1990, RF front-end modules have gradually become the core components of communication devices. Among all RF front-end modules, filters have become the components with the most promising growth momentum and development potential. With rapid development of lineless communication technology, 5G communication protocol has been developed more maturely, and the market has also put forward more stringent standards for performance of RF filters in all aspects. The performance of the filters is determined by the resonator units which are configured to form the filters. Among existing filters, film bulk acoustic resonators have characteristics of small size, low insertion loss, large out-of-band rejection, high quality factor, high operating frequency, large power capacity, and desirable anti-static shock capability, making them one of the most suitable filters for 5G applications. The film bulk acoustic resonators include film bulk acoustic resonators (FBAR) and surface mounted resonators (SMR).

Normally, the film bulk acoustic resonator includes two film electrodes, and a piezoelectric film layer is arranged between two film electrodes. The working principle of the film bulk acoustic resonator is that the piezoelectric film layer is used to generate vibration under the alternating electric field, the vibration excites a bulk acoustic wave propagating along the thickness direction of the piezoelectric film layer, the acoustic wave is reflected back after being transmitted to the boundary (FBAR) or Bragg reflection layer (SMR) between the upper and lower electrodes and the air, and then reflected back and forth inside the film to form an oscillation. Standing wave oscillations are formed when the acoustic wave, which is exactly an odd multiple of a half-wavelength, propagates in a piezoelectric film layer.

The impedance Zp and the quality factor Qp are important indicators to measure the bulk acoustic resonator. The industry also improves the impedance Zp of the bulk acoustic resonator through various efforts and attempts, thereby improving the quality factor Qp. For example, in order to eliminate the noise resonance that may be caused by reflected wave of the lateral bulk acoustic wave at the boundary, the shapes of the effective resonance regions of fabricated film bulk acoustic resonators are mostly irregular polygons, and any two sides of the polygon are not in parallel with each other. For example, in US Patent Publication No. U.S. Pat. No. 9,917,567B2, the resonance region is an irregular polygon, and the opposite sides are not in parallel with each other. It is normally believed by those skilled in the art that such configuration manner may reduce lateral wave leakage and improve the quality factor of the resonator.

However, to form such irregular polygonal effective resonance region in the process flow of fabricating film bulk acoustic resonators, some process problems including optical alignment, online device size measurement and control may exist. From the point of view of process controllability, it is changed to a polygonal pattern with some or all opposite sides in parallel with each other, which may provide more convenience for process processing and online inspection.

### BRIEF SUMMARY OF THE DISCLOSURE

One aspect of the present disclosure provides a film piezoelectric acoustic resonator. The resonator includes an upper electrode, a piezoelectric layer and a lower electrode which are stacked sequentially from a top to a bottom. In an effective resonance region, the upper electrode, the piezoelectric layer and the lower electrode are sequentially overlapped with each other, and a projection of the effective resonance region along a direction of the piezoelectric layer is a hexagon; the hexagon has a first side with a longest length, a second side opposite to the first side, a third side with a shortest length, and a fourth side opposite to the third side; a portion of the upper electrode extending out of the effective resonance region through a first boundary of the effective resonance region is defined as an upper electrode led-out portion; a portion of the lower electrode extending out of the effective resonance region through a second boundary of the effective resonance region is defined as a lower electrode led-out portion; and one of the first boundary and the second boundary is the first side, and the other one of the first boundary and the second boundary is the second side; a first external signal connection terminal is connected to the upper electrode led-out portion, and a second external signal connection terminal is connected to the lower electrode led-out portion; a first opening at the third side passes through the upper electrode, the piezoelectric layer and the lower electrode outside the effective resonance region; and a second opening at the fourth side passes through the upper electrode, the piezoelectric layer and the lower electrode outside the effective resonance region.

Another aspect of the present disclosure provides a filter including a film piezoelectric acoustic resonator. The resonator includes an upper electrode, a piezoelectric layer and a lower electrode which are stacked sequentially from a top to a bottom. In an effective resonance region, the upper electrode, the piezoelectric layer and the lower electrode are sequentially overlapped with each other, and a projection of the effective resonance region along a direction of the piezoelectric layer is a hexagon; the hexagon has a first side with a longest length, a second side opposite to the first side, a third side with a shortest length, and a fourth side opposite to the third side; a portion of the upper electrode extending out of the effective resonance region through a first boundary of the effective resonance region is defined as an upper electrode led-out portion; a portion of the lower electrode extending out of the effective resonance region through a second boundary of the effective resonance region is defined as a lower electrode led-out portion; and one of the first boundary and the second boundary is the first side, and the other one of the first boundary and the second boundary is the second side; a first external signal connection terminal is connected to the upper electrode led-out portion, and a second external signal connection terminal is connected to the lower electrode led-out portion; a first opening at the third side passes through the upper electrode, the piezoelectric layer and the lower electrode outside the effective resonance region; and a second opening at the fourth side passes through the upper electrode, the piezoelectric layer and the lower electrode outside the effective resonance region.

Another aspect of the present disclosure provides an electronic apparatus including a filter. The filter includes a film piezoelectric acoustic resonator. The resonator includes an upper electrode, a piezoelectric layer and a lower electrode which are stacked sequentially from a top to a bottom. In an effective resonance region, the upper electrode, the piezoelectric layer and the lower electrode are sequentially overlapped with each other, and a projection of the effective resonance region along a direction of the piezoelectric layer is a hexagon; the hexagon has a first side with a longest length, a second side opposite to the first side, a third side with a shortest length, and a fourth side opposite to the third side; a portion of the upper electrode extending out of the effective resonance region through a first boundary of the effective resonance region is defined as an upper electrode led-out portion; a portion of the lower electrode extending out of the effective resonance region through a second boundary of the effective resonance region is defined as a lower electrode led-out portion; and one of the first boundary and the second boundary is the first side, and the other one of the first boundary and the second boundary is the second side; a first external signal connection terminal is connected to the upper electrode led-out portion, and a second external signal connection terminal is connected to the lower electrode led-out portion; a first opening at the third side passes through the upper electrode, the piezoelectric layer and the lower electrode outside the effective resonance region; and a second opening at the fourth side passes through the upper electrode, the piezoelectric layer and the lower electrode outside the effective resonance region.

Other aspects of the present disclosure can be understood by those skilled in the art in light of the description, the claims, and the drawings of the present disclosure.

### BRIEF DESCRIPTION OF THE DRAWINGS

FIG. 1 illustrates a structural schematic of a film piezoelectric acoustic resonator according to exemplary embodiments of the present disclosure.

FIG. 2A illustrates a cross-sectional view along an X-X direction of FIG. 1.

FIG. 2B illustrates a cross-sectional view along a Y-Y direction of FIG. 1.

FIG. 3 illustrates a relationship between resonance impedance Zp and quality factor Qp.

FIG. 4 illustrates a simulation graph corresponding to a resonator structure according to exemplary embodiments of the present disclosure.

FIG. 5 illustrates a simulation graph corresponding to an effective resonance region being a pentagon.

FIG. 6 illustrates a schematic of a structure that a non-longest side is used as an electrode led-out side and a first opening is formed at a non-shortest side.

FIG. 7 illustrates a simulation graph corresponding to a structure of FIG. 6.

FIG. 8 illustrates a simulation graph of a resonator that a piezoelectric material is aluminum nitride.

FIG. 9 illustrates a simulation graph of a resonator that a piezoelectric material is zinc oxide.

FIG. 10 illustrates a simulation graph of a resonator that a piezoelectric material is lead zirconate titanate.

FIG. 11 illustrates a schematic of a lattice structure of aluminum nitride.

FIGS. 12A and 12B respectively illustrate a schematic and a corresponding simulation graph of a structure that all opposite sides of an effective resonance region are in parallel with each other.

FIGS. 13A and 13B respectively illustrate a schematic and a corresponding simulation graph of a structure that an effective resonance region has two pairs of parallel opposite sides.

FIGS. 14A and 14B respectively illustrate a schematic and a corresponding simulation graph of a structure that all opposite sides of an effective resonance region are not in parallel with each other.

FIGS. 15A and 15B respectively illustrate a schematic and a corresponding simulation graph of a structure that an effective resonance region has only one pair of parallel opposite sides.

FIGS. 16A and 16B respectively illustrate a schematic and a corresponding simulation graph of a structure that opposite sides of an effective resonance region are in parallel with each other and have an equal length.

FIGS. 17A and 17B respectively illustrate a schematic and a corresponding simulation graph of a structure that opposite sides of an effective resonance region are in parallel with each other and have unequal lengths.

FIGS. 18A and 18B respectively illustrate a schematic and a corresponding simulation graph of a structure that a second side of an effective resonance region is a second longest side.

FIGS. 19A and 19B respectively illustrate a schematic and a corresponding simulation graph of a structure that a second side of an effective resonance region is not a second longest side.

FIGS. 20A and 20B respectively illustrate a schematic and a corresponding simulation graph of a structure that a first side is adjacent to a third side, and a length of the first side is greater than 1.25 times a length of the third side.

FIGS. 21A and 21B respectively illustrate a schematic and a corresponding simulation graph of a structure that a first side is adjacent to a third side, and a length of the first side is not greater than 1.25 times a length of the third side.

### DETAILED DESCRIPTION

The present disclosure is further described in detail with reference to the accompanying drawings and specific embodiments hereinafter. The advantages and features of the present disclosure may be more apparent according to the following description and the accompanying drawings. However, it should be noted that the concept of the technical solution of the present disclosure may be implemented in various different forms and may not be limited to specific embodiments set forth herein. The accompanying drawings may be all in simplified forms and non-precise scales and may be merely for convenience and clarity of the purpose of the embodiments of the present disclosure.

It should be understood that when an element or layer is referred to as being “on” “adjacent to”, “connected with”, or “coupled to” other elements or layers, the element or layer may be directly on the other elements or layers, or may be adjacent to, connected, or coupled to other elements or layers; or there may be intermediate elements or layers. In contrast, when an element is referred to as being “directly on”, “directly adjacent to”, “directly connected with”, or “directly coupled to” other elements or layers, there may not be intermediate elements or layers. It should be understood that, although the terms first, second, third and the like may be configured to describe various elements, components, regions, layers and/or sections, these elements, components, regions, layers and/or sections should not be limited by these terms. These terms are only used to distinguish one element, component, region, layer or section from another element, component, region, layer or section. Thus, the first element, component, region, layer or section discussed below could be termed the second element, component, region, layer or section without departing from the scope of the present disclosure.

Spatial relation terms such as “under”, “below”, “beneath”, “above”, “over” and the like may be configured herein for convenience of description to describe the relationship of one element or feature to other elements or features shown in the drawings. It should be understood that spatial relation terms may be intended to include different orientations of the device in use and operation in addition to the orientation shown in the drawings. For example, if the device in the drawings is turned over, then elements or features described as “below” or “beneath” or “under” other elements or features would then be oriented “above” the other elements or features. Thus, exemplary terms “below” and “under” may include both up and down orientations. The device may be otherwise oriented (rotated 90 degrees or at other orientations) and the spatial descriptors used herein may be interpreted accordingly.

The terminology used herein may be for the purpose of describing particular embodiments only and may not be intended to limit the present disclosure. As used herein, the singular forms “a”, “an”, and “the/said” may be intended to include plural forms as well, unless the context clearly dictates otherwise. It should also be understood that terms “contain” and/or “include”, when used in the specification, may be configured to determine the presence of stated features, integers, steps, operations, elements and/or components, but may not exclude one or more other presence or addition of features, integers, steps, operations, elements, parts and/or groups. As used herein, the term “and/or” may include any and all combinations of associated listed items.

If the method described herein includes a series of steps, the step order presented herein may not be necessarily the only order in which the steps is performed, and some of the steps may be omitted and/or other steps, which are not described herein, may be added to the method. If components in one of the drawings are same as components in other drawings, although the components may be easily recognized in all drawings, in order to make the description of the drawings clearer, labels of all same components may not be marked in each drawing in the present specification.

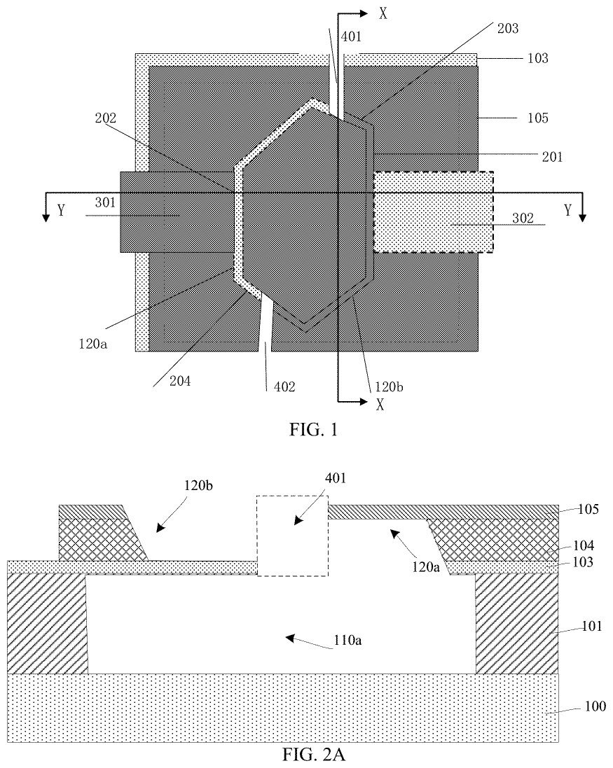

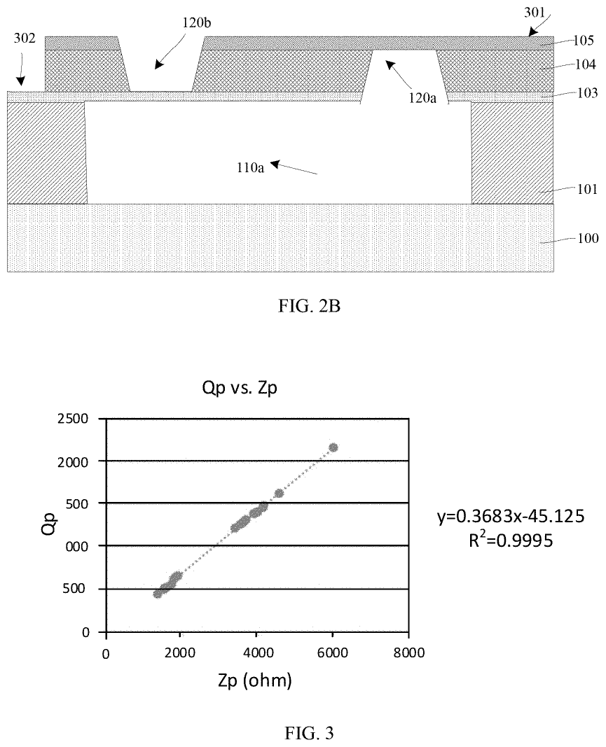

A film piezoelectric acoustic resonator is provided in one embodiment of the present disclosure. FIG. 1 illustrates a structural schematic of a film piezoelectric acoustic resonator according to exemplary embodiments of the present disclosure. FIG. 2A illustrates a cross-sectional view along an X-X direction of FIG. 1. FIG. 2B illustrates a cross-sectional view along a Y-Y direction of FIG. 1. Referring to FIGS. 1, 2A and 2B, the film piezoelectric acoustic resonator may include an upper electrode 105, a piezoelectric layer 104 and a lower electrode 103 which are stacked sequentially from top to bottom.

In an effective resonance region, the upper electrode 105, the piezoelectric layer 104 and the lower electrode 103 may be overlapped with each other sequentially, and the projection of the effective resonance region along the direction of the piezoelectric layer 104 may be a hexagon.

The hexagon has a first side 201 with the longest length, a second side 202 opposite to the first side 201, a third side 203 with the shortest length, and a fourth side 204 opposite to the third side 203.

The upper electrode 105 extending out of the effective resonance region through the first boundary of the effective resonance region is defined as an upper electrode led-out portion 301, the lower electrode extending out of the effective resonance region through the second boundary of the effective resonance region is defined as a lower electrode led-out portion 302; one of the first boundary and the second boundary may be the first side 201, and the other one may be the second side 202.

A first external signal connection terminal may be connected to the upper electrode led-out portion 301, and a second external signal connection terminal may be connected to the lower electrode led-out portion 302.

A first opening 401 located at the third side 203 may pass through the upper electrode 105, the piezoelectric layer 104 and the lower electrode 104 outside the effective resonance region.

A second opening 402 located at the fourth side 204 may pass through the upper electrode 105, the piezoelectric layer 104 and the lower electrode 103 outside the effective resonance region.

In one embodiment, the structure of the resonator may be that an upper electrode 105 may be formed with a first trench 120b passing through the upper electrode 105, and the lower electrode 103 may be formed with a second trench 120a passing through the lower electrode 103; the first trench 120b may be on the opposite side of the upper electrode led-out portion 301, and the second trench 120a may be on the opposite side of the lower electrode led-out portion 302; and the first trench 120b and the second trench 120a may together form the boundary of the effective resonance region, and the projections of two trenches may form a hexagon. The hexagon may be a closed hexagon, or a spacing may be formed at the junction of the first trench 120b and the second trench 120a. Referring to FIG. 1, the first trench 120b and the second trench 120a may be respectively two partial-ring shapes, and the projections of the first trench 120b and the second trench 120a along the direction of the piezoelectric layer 104 may form a closed hexagon.

Referring to FIGS. 1, 2A and 2B, the upper electrode 105 extending out of the effective resonance region through the first boundary of the effective resonance region is defined as the upper electrode led-out portion 301, and the lower electrode 103 extending out of the effective resonance region through the second boundary of the effective resonance region is defined as a lower electrode led-out portion 302. The upper electrode led-out portion 301 may be connected to the first external signal connection terminal, and the lower electrode led-out portion 302 may be connected to the second external signal connection terminal. In one embodiment, the first boundary may be the second side 202, and the second boundary may be the first side 201.

In one embodiment, the first trench 120b may be a partial-ring shape, and the first trench 120b may be disposed opposite to the upper electrode led-out portion 301, that is, the first trench 120b may be not at the position of the upper electrode led-out portion 301; and the second trench 120a may be a partial-ring shape, and the second trench 120a may be disposed opposite to the lower electrode led-out portion 302, that is, the second trench 120a may be not at the position of the lower electrode led-out portion 302. The upper electrode led-out portion 301 may be led out from the resonance region along the direction perpendicular to the second side 202, and the lower electrode led-out portion 302 may be led out from the resonance region along the direction perpendicular to the first side 201. The second side 202 is the second longest side of the hexagon, that is, the upper electrode led-out portion 301 and the lower electrode led-out portion 302 may be respectively led out through two opposite longest sides of the hexagon. The series resistance may be reduced by leading out the electrodes through the longest sides. When both the upper electrode and the lower electrode are led out through the longest sides, the series resistance may be reduced to the greatest extent.

The first opening 401 may be formed at the third side 203 and pass through the upper electrode 105, the piezoelectric layer 104 and the lower electrode 103 outside the effective resonance region. The second opening 402 may be formed at the fourth side 204 and may pass through the upper electrode 10, the piezoelectric layer 104 and the lower electrode 103 outside the effective resonance region. In one embodiment, the first opening 401 and the second opening 402 may be a long strip shape and extend outside of the boundary between the upper electrode 105 and the lower electrode 103 along the horizontal direction (in parallel with the piezoelectric layer). A region which is opposite to the upper electrode and the lower electrode may be in the inactive region outside the effective resonance region of the resonator, which is referred to as a parasitic region. The first opening 401 or the second opening 402 may cut off the upper electrode 105 and the lower electrode 103 of the parasitic region, which may reduce parasitic parameters, improve the quality factor of the resonator, and further improve device performance. The first opening 401 and the second opening 402 may also be filled with insulating materials. Disposing the opening at the shortest side may shorten the process time and improve the resonator fabrication efficiency. In one embodiment, the third side 203 and the fourth side 204 may be in parallel with or approximately in parallel with each other, and the fourth side 204 may be the second shortest side of the hexagon. It should be noted that “approximately in parallel with” in the present disclosure may indicate that the angle of two sides may be allowed to have a process error of plus or minus 5 degrees.

In one embodiment, the first opening 401 and the second opening 402 may be respectively disposed at two junctions of the first trench 120b and the second trench 120a.

The quality factor of the resonator is the main parameter used to determine the performance of the resonator. The quality factor and the resonant impedance Zp of the resonator have a highly linear relationship. Referring to FIG. 3, FIG. 3 illustrates a relationship between the resonance impedance Zp and the quality factor Qp; Qp=0.3683*Zp−45.125, and the linear correlation coefficient R²=0.9995. R²=1 indicates a linear relationship. The above relationship may be obtained by ‘MBVD model’ and ‘particle swarm algorithm fitting’. ‘MBVD model’ and ‘particle swarm algorithm fitting’ are common knowledge of those skilled in the art, and the derivation process for obtaining the results is not described herein. It can be seen from the above results that when the Zp of the resonator is relatively high, it indicates that the quality factor Qp of the resonator is relatively high.

The inventor had completed multiple sets of simulation experiments on the shape of the effective resonance region, the positions where the upper electrode led-out portion and the lower electrode led-out portion are led out from the effective resonance region to the outside of the effective resonance region, and the positions of forming the openings passing through the upper electrode, the piezoelectric layer and the lower electrode. When the shape of the effective resonance region is hexagonal, the longest side (first side) and the opposite side (second side) of the effective resonance region are respectively used as the led-out sides of the upper electrode led-out portion and the lower electrode led-out portion, the first opening and the second opening (to prevent parasitic capacitance of the ineffective region) passing through the piezoelectric stack structure of the ineffective region are respectively formed at the shortest side (third side) and the opposite side (fourth side), that is, when these conditions are satisfied, the inventor had found that the impedance Zp and the quality factor Qp of the bulk acoustic resonator are desirable through the simulation data. The modeling had been performed based on above-mentioned structure, and the simulation graphs are used to for illustration hereinafter. It should be noted that the data of the simulation graphs provided in present disclosure uses following model parameters: the material of the upper electrode and the lower electrode may be molybdenum, the thickness may be 0.24 micron, the material of the piezoelectric layer may be aluminum nitride, and the thickness of the piezoelectric layer may be 0.9 micron. The data marked at the interior angles in the graph are the degrees of the interior angles.

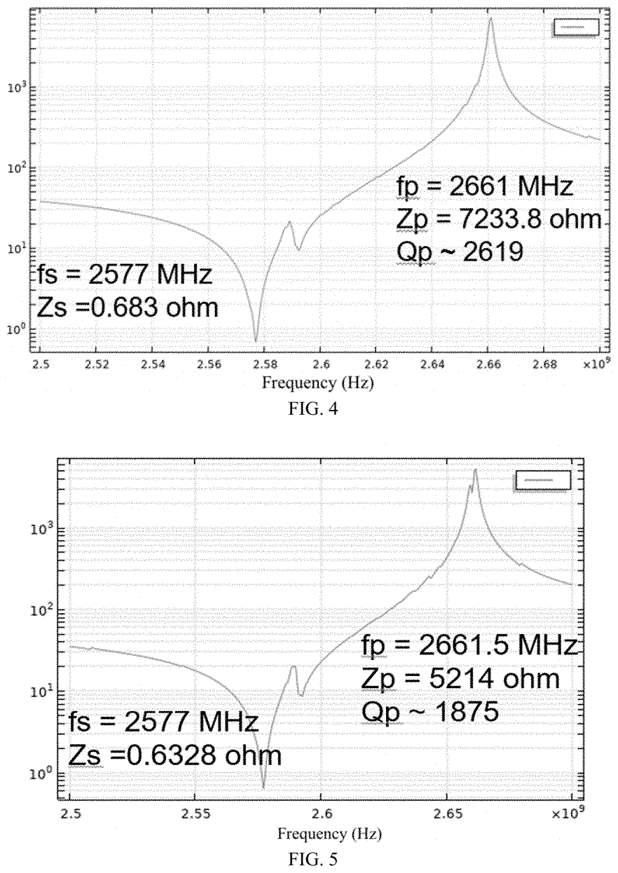

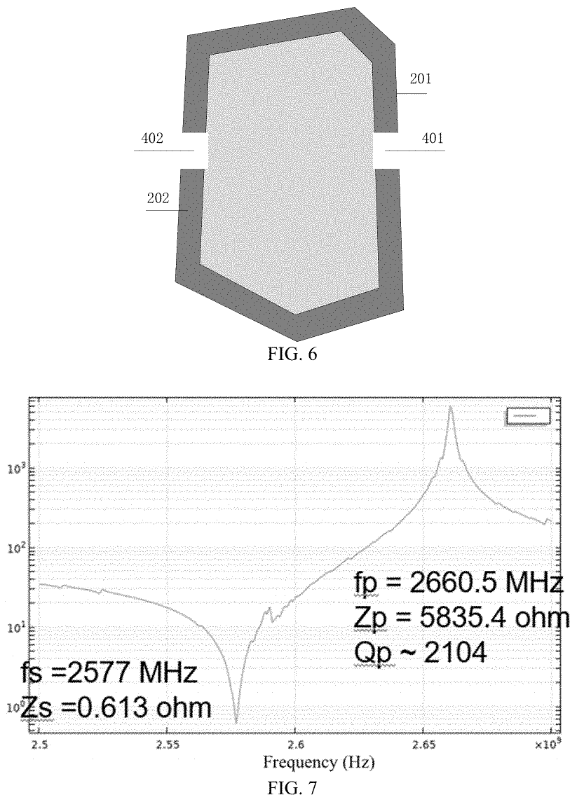

FIG. 4 illustrates a simulation graph corresponding to a resonator structure according to exemplary embodiments of the present disclosure. FIG. 5 illustrates a simulation graph corresponding to an effective resonance region being a pentagon. FIG. 6 illustrates a schematic of a structure that a non-longest side is used as an electrode led-out side and a first opening is formed at a non-shortest side. FIG. 7 illustrates a simulation graph corresponding to a structure of FIG. 6.

In FIG. 4, the value of the resonance impedance Zp is 7233.8 ohms, and the value of the quality factor Qp is 2619. In FIG. 5, the value of the resonant impedance Zp is 5214 ohms, and the value of the quality factor Qp is 1875. In FIG. 7, the value of the resonance impedance Zp is 5835.4 ohms, and the value of the quality factor Qp is 2104.

The above data demonstrates that when the shape of the effective resonance region is hexagonal, the longest side (first side) and the opposite side (second side) of the effective resonance region are respectively used as the led-out sides of the upper electrode led-out portion and the lower electrode led-out portion, the first opening and the second opening (to prevent parasitic capacitance of the ineffective region) passing through the piezoelectric stack structure of the ineffective region are respectively formed at the shortest side (third side) and the opposite side (fourth side), that is, when these conditions are satisfied, the impedance Zp and the quality factor Qp of the bulk acoustic resonator may both be desirable.

In addition, on the basis that the resonator maintains above-mentioned structure, the inventor had studied the structure of the piezoelectric layer material to obtain following conclusions.

1) When the number of sides of the crystal plane of the lattice structure is also six, the impedance Zp and the quality factor Qp of the bulk acoustic resonator may be desirable.

2) When the number of sides of the crystal plane of the lattice structure is also six, and the shape of the hexagon is substantially consistent with the hexagon shape of the effective resonance region (the interior angles corresponding to the two hexagons are substantially equal to each other), the impedance Zp and quality factor Qp of the bulk acoustic resonator may be desirable.

3) When the piezoelectric material of hexagonal lattice is used, and three pairs of opposite sides of the hexagon in the effective resonance region are in parallel with each other, the interior angles are all 120 degrees, and the opposite sides in parallel with each other are unequal in length, the resonator may have desirable impedance Zp and quality factor Qp.

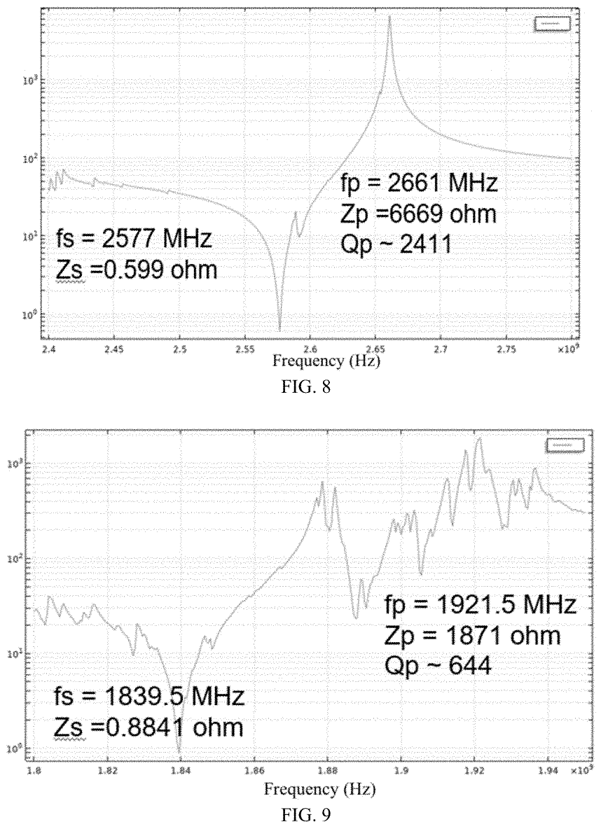

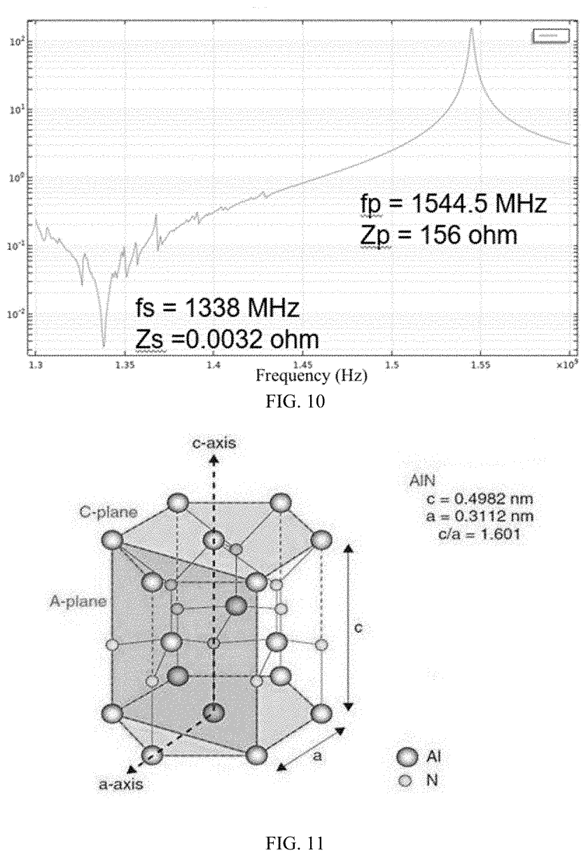

Referring to FIGS. 8-10, FIGS. 8-10 have same other structures except for the piezoelectric layer material. FIG. 8 illustrates a simulation graph of a resonator that a piezoelectric material is aluminum nitride. FIG. 9 illustrates a simulation graph of a resonator that a piezoelectric material is zinc oxide. FIG. 10 illustrates a simulation graph of a resonator that a piezoelectric material is lead zirconate titanate. Aluminum nitride has a hexagonal lattice structure; and neither zinc oxide nor lead zirconate titanate has a hexagonal lattice structure.

In FIG. 8, the value of the resonance impedance Zp is 6669 ohms, and the value of the quality factor Qp is 2411. In FIG. 9, the value of the resonant impedance Zp is 1874 ohms, and the value of the quality factor Qp is 644. In FIG. 10, the value of the resonant impedance Zp is 156 ohms, and the value of the quality factor Qp is 12. Above-mentioned simulation results show that the quality factor of the resonator is relatively high when the shape of the effective resonance region is hexagonal, and the material of the piezoelectric layer is a hexagonal lattice structure. The hexagonal lattice structure of aluminum nitride is analyzed hereinafter.

Referring to FIG. 11, FIG. 11 illustrates a schematic of a lattice structure of aluminum nitride. Aluminum nitride, a covalent bond compound, is an atomic crystal, which belongs to the crystal structure of diamond-like nitride and wurtzite; the lattice of aluminum nitride is hexagonal; atoms are arranged in a regular hexagon; and six apex angles are all 120 degrees. The lattice constants a=0.3112 nm, c=0.4980 nm, an Al atom forms a tetrahedron with surrounding four N atoms, where the length of each of three Al—N bonds is 1.885 Å, and the length of the Al—N bond along the C axis is 1.917 Å. Due to the integrity of the unit cell, the lattice vibration is based on the unit cell. If a part of the unit cell is outside the working region, a part of mechanical vibration energy may inevitably be lost outside the working region. When the working region of the resonator is also designed as a hexagon with an apex angle of 120 degrees (in one embodiment, all interior angles of the hexagon in the effective resonance region may be 120 degrees; and in other embodiments, the interior angle value range of the hexagon may be that the maximum interior angle is 140 degrees and the minimum interior angle is 100 degrees), such design may best fit the lattice shape, and the most complete lattices may be included in the working region. In such case, only the fewest unit cells may cross the boundary of the working region, thereby reducing the energy loss of mechanical vibration. Such arrangement may achieve consistency with spatial geometric continuation of the lattice of aluminum nitride or other piezoelectric crystal materials with a hexagonal lattice structure, because these piezoelectric crystals may have exactly a hexagonal lattice shape along the horizontal direction. Meanwhile, the C axis of the hexagonal lattice may be kept nearly perpendicular to the plane of the piezoelectric layer, and the upper and lower surfaces of the piezoelectric layer may be kept in parallel with each other and nearly perpendicular to the C axis in such solution, which may be beneficial for achieving the best longitudinal piezoelectric induction and corresponding bulk acoustic wave characteristics.

In addition, the inventor had changed the shape of the hexagon to continue to complete comparative experiments. The experimental results show that when the opposite sides of the hexagon are in parallel with each other, the impedance Zp and the quality factor Qp of the bulk acoustic resonator may be desirable, which is demonstrated by following simulation graphs.

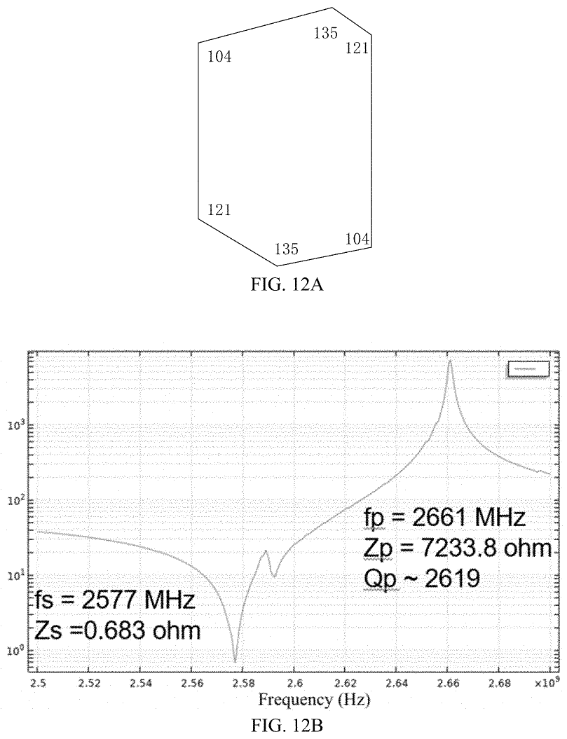

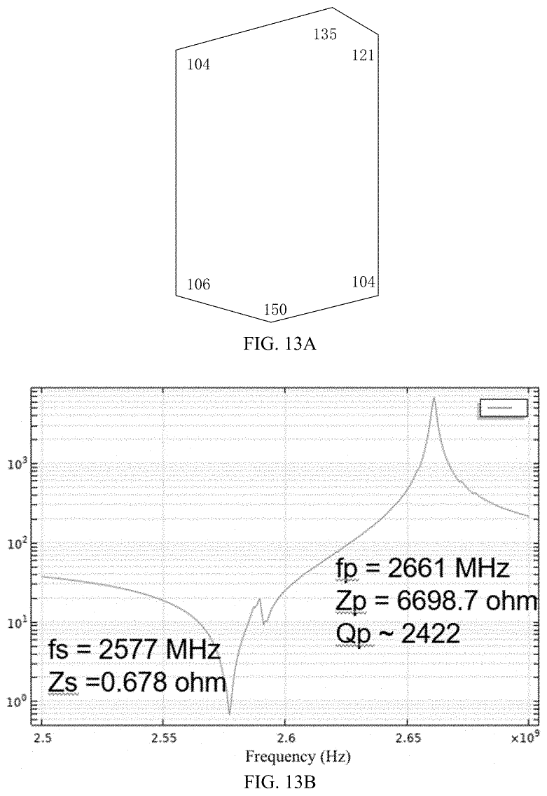

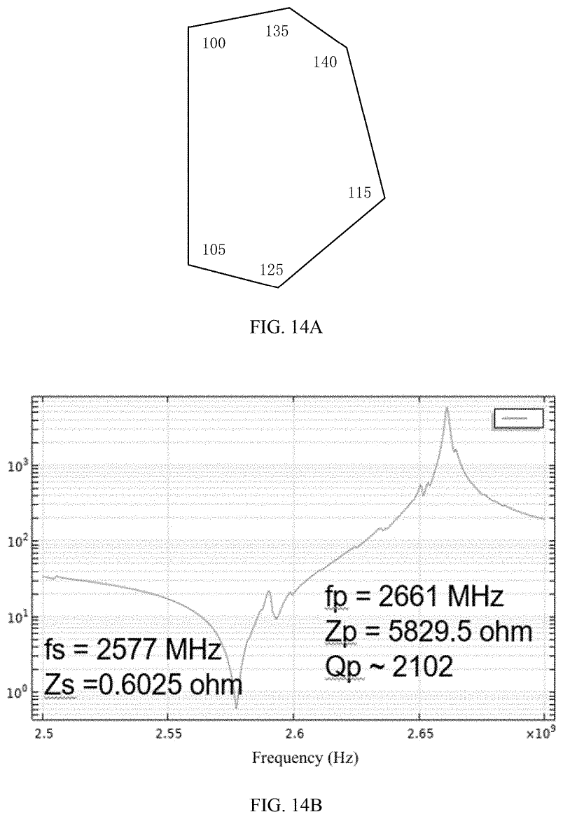

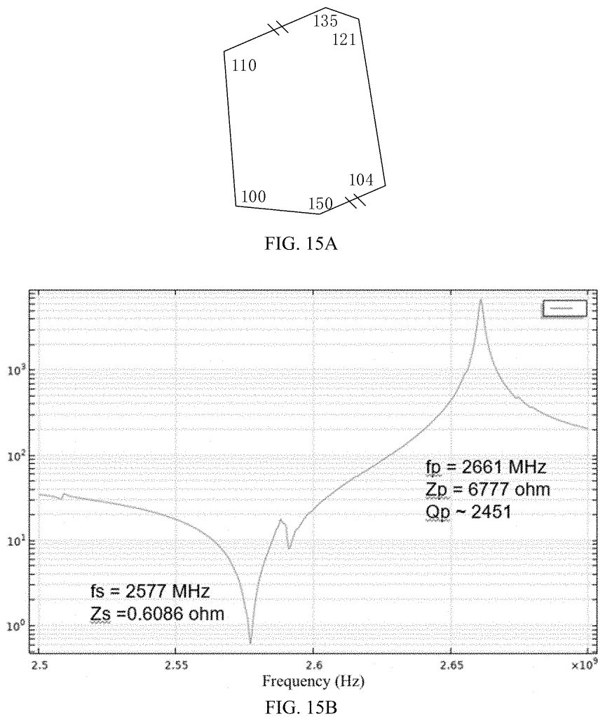

FIGS. 12A and 12B respectively illustrate a schematic and a corresponding simulation graph of a structure that all opposite sides of an effective resonance region are in parallel with each other. FIGS. 13A and 13B respectively illustrate a schematic and a corresponding simulation graph of a structure that an effective resonance region has two pairs of parallel opposite sides. FIGS. 14A and 14B respectively illustrate a schematic and a corresponding simulation graph of a structure that all opposite sides of an effective resonance region are not in parallel with each other. FIGS. 15A and 15B respectively illustrate a schematic and a corresponding simulation graph of a structure that an effective resonance region has only one pair of parallel opposite sides.

In FIG. 12B, the value of the resonance impedance Zp is 7233.8 ohms, and the value of the quality factor Qp is 2619. In FIG. 13B, the value of the resonance impedance Zp is 6698.7 ohms, and the value of the quality factor Qp is 2422. In FIG. 14B, the value of the resonance impedance Zp is 5829.5 ohms, and the value of the quality factor Qp is 2102. In FIG. 15B, the value of the resonance impedance Zp is 6777 ohms, and the value of the quality factor Qp is 2451.

Above data may indicate that when the opposite sides of the hexagon are in parallel with each other, no matter how many pairs of opposite sides are in parallel with each other, the impedance Zp and quality factor Qp of the bulk acoustic resonator may be relatively desirable.

It should be noted that in the process of fabricating the film bulk acoustic resonator to form the effective resonance region of an irregular polygon, some problems including optical alignment and online device size measurement may exist; however, the polygonal pattern with some or all of the opposite sides in parallel with each other may provide more convenience for process processing and online inspection. When the opposite sides of the effective resonance region are in parallel with each other, the quality factor of the resonator may be improved, and the processing difficulty may also be reduced.

On the basis that the opposite sides of the hexagon are in parallel with each other, the inventor had continued the comparative experiments, and found that when the lengths of two parallel opposite sides are not equal to each other, the quality factor of the resonator may be higher.

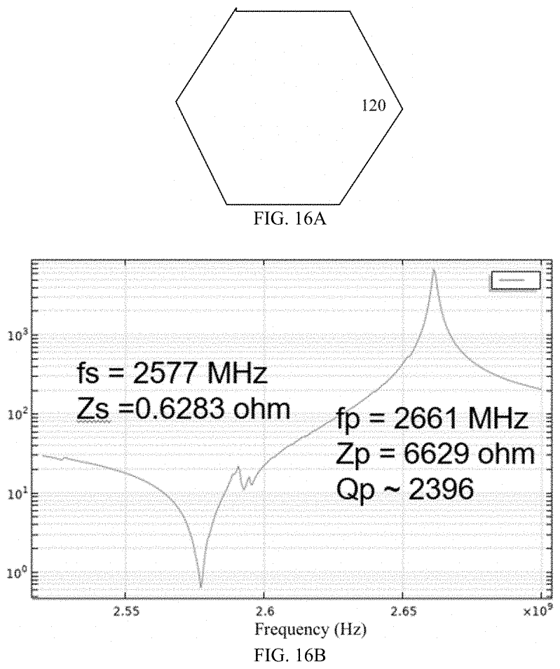

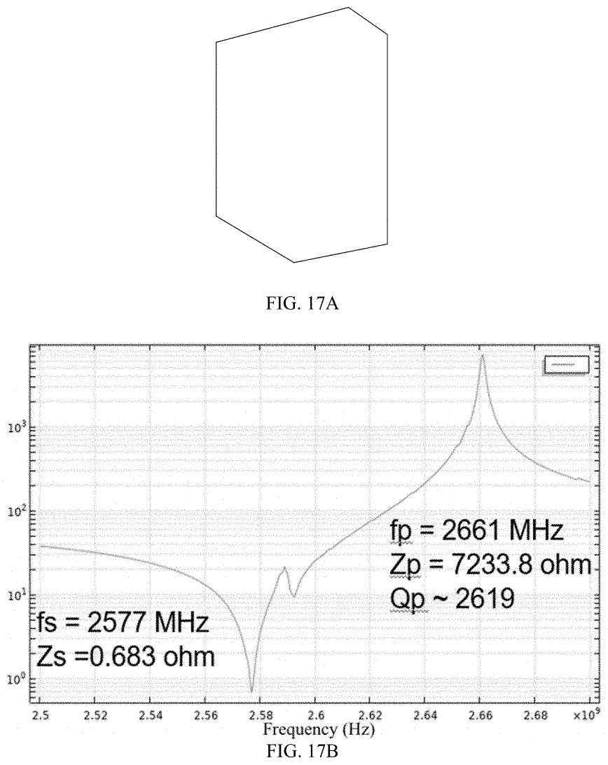

FIGS. 16A and 16B respectively illustrate a schematic and a corresponding simulation graph of a structure that opposite sides of the effective resonance region are in parallel with each other and have an equal length. FIGS. 17A and 17B respectively illustrate a schematic and a corresponding simulation graph of a structure that opposite sides of the effective resonance region are in parallel with each other and have unequal lengths.

In FIG. 16B, the value of the resonance impedance Zp is 6629 ohms, and the value of the quality factor Qp is 2396; and in FIG. 17B, the value of the resonance impedance Zp is 7233.8 ohms, and the value of the quality factor Qp is 2619. It can be seen from above-mentioned comparison that the quality factor of the opposite sides of the resonance region in parallel with each other and having an equal length may be higher than the quality factor of the opposite sides of the resonance region in parallel with each other and having unequal lengths.

Regarding the lengths of the first side and the second side, the inventor had also completed the simulation study and found that when the second side is the second longest side of the hexagon, the resonator may have a relatively high quality factor.

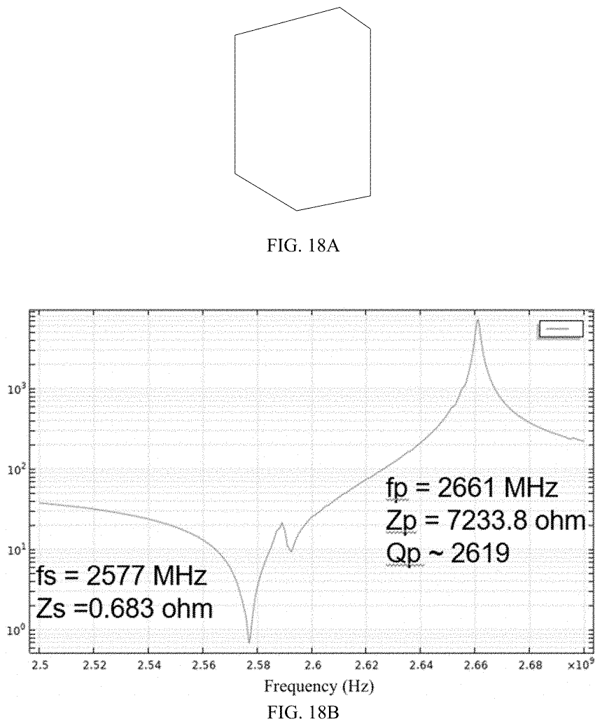

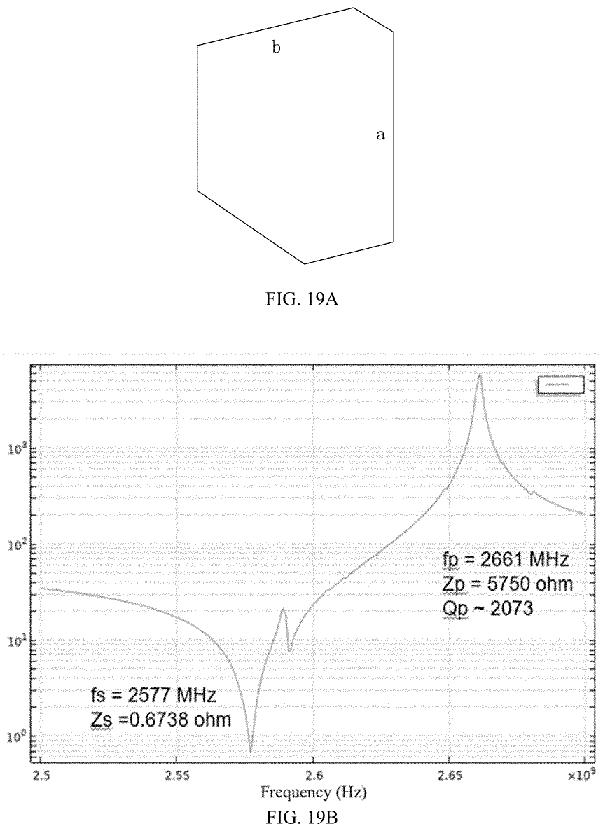

FIGS. 18A and 18B respectively illustrate a schematic and a corresponding simulation graph of a structure that the second side of the effective resonance region is a second longest side; and FIGS. 19A and 19B respectively illustrate a schematic and a corresponding simulation graph of a structure that the second side of the effective resonance region is not a second longest side, where a is the longest side, and b is a second-longest side.

In FIG. 18B, the value of the resonance impedance Zp is 7233.8 ohms, and the value of the quality factor Qp is 2619; and in FIG. 19B, the value of the resonance impedance Zp is 5750 ohms, and the value of the quality factor Qp is 2073.

It had been found from the simulation that when the first side and the third side of the hexagon are adjacent to each other, and the length of the first side is greater than 1.25 times the length of the third side, the resonator may have a relatively high quality factor.

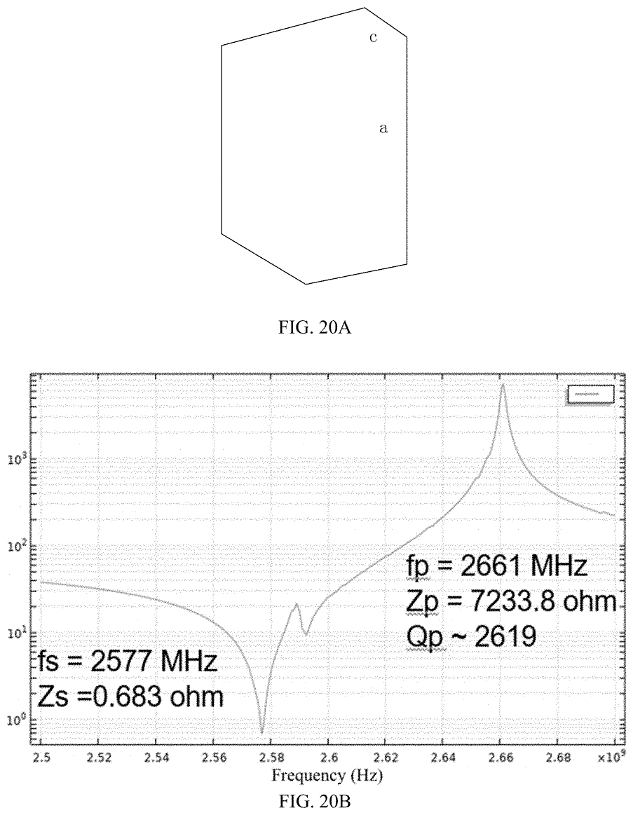

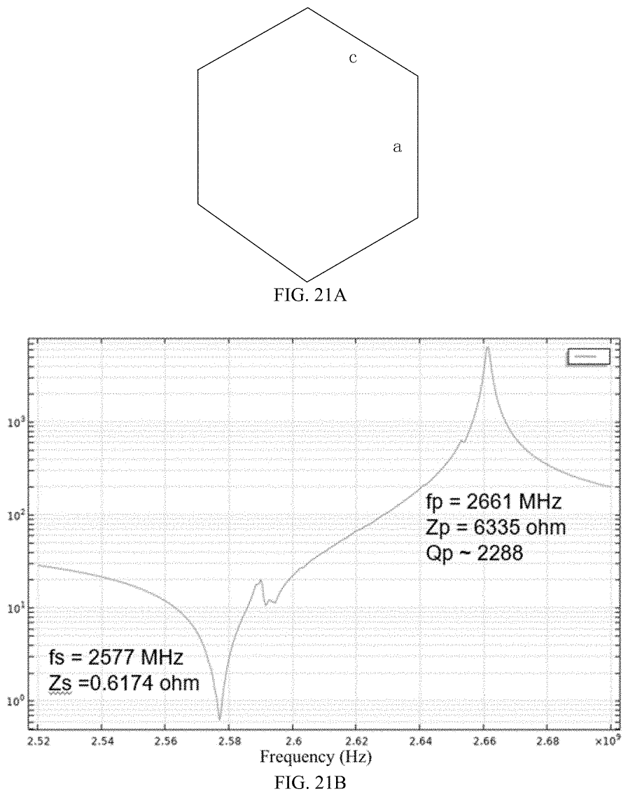

FIGS. 20A and 20B respectively illustrate a schematic and a corresponding simulation graph of a structure that the first side is adjacent to the third side, and a length of the first side is greater than 1.25 times a length of the third side, where a is the longest side, c is the shortest side, and the longest side is 5.15 times the shortest side. FIGS. 21A and 21B respectively illustrate a schematic and a corresponding simulation graph of a structure that the first side is adjacent to the third side, and a length of the first side is not greater than 1.25 times a length of the third side, where a is the longest side, c is the shortest side, and the longest side is 1.13 times the shortest side. In FIG. 20B, the value of the resonance impedance Zp is 7233.8 ohms, and the value of the quality factor Qp is 2619; and in FIG. 21B, the value of the resonance impedance Zp is 6335 ohms, and the value of the quality factor Qp is 2288.

It should be noted that, in one embodiment, the first trench 120b and the second trench 120a may respectively be two partial-rings, which may be projected as the hexagon; and the boundaries of the upper and lower electrodes may together form the effective resonance region. The establishment of the above model and the simulation results are also based on this situation of the resonator. In other embodiments, the first trench 120b or the second trench 120a may be multiple spaced sections, and the projections of the first trench 120b or the second trench 120a may form a closed hexagon. Or the formation of the effective resonance region may have following two cases.

1) Trenches may be included in the piezoelectric layer; a part of the boundary of the piezoelectric layer may form a part of the boundary of the effective resonance region, and another part of the boundary of the effective resonance region may be formed by a part of the boundary of the upper electrode or the lower electrode.

2) Trenches may be included in the piezoelectric layer; and the boundaries of the upper electrode, the lower electrode and the piezoelectric layer may together form the effective resonance region of the resonator.

In addition, in one embodiment, the first opening and the second opening may be respectively formed at two opposite shortest sides; and the two shortest sides are in parallel with each other. In other embodiments, the fourth side 204 may not be in parallel with the third side 203, and the fourth side 204 may not be the second shortest side. Or the first opening 401 may be formed at the included angle of the third side 203; and/or the second opening 402 may be formed at the included angle of the fourth side 204. Moreover, the first opening 401 and the second opening 402 may both be connected to the first trench 120b or may both be connected to the second trench 120a, or one of the first opening 401 and the second opening 402 may be connected to the first trench 120b, and the other one of the first opening 401 and the second opening 402 may be connected to the second trench 120a.

The inventor had also performed simulation and comparative analysis for above-mentioned manners to form the effective resonance region, as well as different forms and positions of the first opening and the second opening; and found that above structural changes may not affect the simulation and comparison conclusions, which may not be described in detail herein.

In one embodiment, the first trench 120b and the second trench 120a may pass through the upper electrode 105 and the lower electrode 103 respectively. In other embodiments, the bottom surface of the first trench 120b may be on the lower surface of the piezoelectric layer 104 or in the middle of the piezoelectric layer 104; and/or the bottom surface of the second trench 120a may be on the upper surface of the piezoelectric layer 104 or in the middle of the piezoelectric layer 104. When the bottom surface of the first trench 120b or the second trench 120a is in the middle of the piezoelectric layer 104 or passes through the piezoelectric layer 104, the side of the piezoelectric layer 104 may be in contact with air. Due to the mismatch between the acoustic impedance of the piezoelectric layer 104 and the acoustic impedance of the air, when the transverse acoustic wave in the piezoelectric layer 104 propagates to the junction, the acoustic wave may be reflected back into the piezoelectric layer 104, which may reduce the lateral acoustic wave leakage and improve the quality factor of the resonator. It can be understood that when the first trench 120b and the second trench 120a pass through the piezoelectric layer 104, the effect of preventing the lateral acoustic wave leakage may be desirable; and when the bottom surfaces of the first trench 120b and the second trench 120a are in the piezoelectric layer 104, the resonator may have desirable structural strength, thereby improving the yield and stability of the resonator.

The materials of the upper electrode 105 and the lower electrode 103 of the film acoustic resonator in one embodiment may be any suitable conductive materials or semiconductor materials known to those skilled in the art. The conductive material may be a metal material with conductive properties, which is made of one of metals including molybdenum (Mo), aluminum (Al), copper (Cu), tungsten (W), tantalum (Ta), platinum (Pt), ruthenium (Ru), rhodium (Rh), iridium (Ir), chromium (Cr), titanium (Ti), gold (Au), osmium (Os), rhenium (Re), palladium (Pd), or a stacked layer made of above-mentioned metals. The semiconductor material may be, for example, silicon (Si), germanium (Ge), silicon germanium (SiGe), silicon carbide (SiC), silicon germanium carbide (SiGeC), or the like.

In one embodiment, the resonator may further include a carrier substrate; the carrier substrate may include an acoustic reflection structure; and the effective resonance region may be above the region enclosed by the acoustic reflection structure. The carrier substrate may be a single-layer structure or a multi-layer structure, and when the carrier substrate is a single-layer structure, the acoustic reflection structure may be in the carrier substrate. Referring to FIG. 1, in one embodiment, the carrier substrate may be a double-layer structure including the first substrate 100 and the support layer 101; the support layer 101 may be bonded on the first substrate 100 by a bonding manner; and the bonding manner may include fusion bonding or dry film bonding. The acoustic reflection structure may be the first cavity 110a in the support layer 101. Obviously, the acoustic reflection structure formed in the support layer 101 may also be a Bragg acoustic reflection layer. The acoustic reflection structure may utilize the acoustic impedance mismatch to reflect the acoustic wave, propagating from the piezoelectric layer 104 and the lower electrode 103 to the reflection surface of the acoustic reflection structure, back into the piezoelectric layer, thereby reducing the energy loss of the acoustic wave and improving the quality factor of the resonator.

The material of the first substrate 100 may be at least one of the following mentioned materials, including silicon (Si), germanium (Ge), silicon germanium (SiGe), silicon carbide (SiC), silicon germanium carbide (SiGeC), indium arsenide (InAs), gallium arsenide (GaAs), indium phosphide (InP) or other IIIN compound semiconductors, and may also be ceramic substrates such as alumina, quartz or glass substrates, and the like. The material of the support layer 101 may be, for example, one or a combination of silicon dioxide (SiO₂), silicon nitride (Si₃N₄), aluminum oxide (Al₂O₃) and aluminum nitride (AlN).

The present disclosure also provides a filter including above-mentioned resonators, and the connection manner of each resonator in the filter may be configured according to actual needs.

The present disclosure also provides an electronic apparatus including above-mentioned filter, such as a mobile phone and the like.

From the above-mentioned embodiments, it can be seen that the technical solutions provided by the present disclosure may achieve at least following beneficial effects.

When the shape of the effective resonance region is hexagonal, the longest side (first side) and the opposite side (second side) of the effective resonance region are respectively used as the led-out sides of the upper electrode led-out portion and the lower electrode led-out portion, the first opening and the second opening (to prevent parasitic capacitance of the ineffective region) passing through the piezoelectric stack structure of the ineffective region are respectively formed at the shortest side (third side) and the opposite side (fourth side), that is, when these conditions are satisfied, the piezoelectric field analysis and simulation may indicate that the impedance Zp and quality factor Qp of the bulk acoustic resonator may be desirable. Selecting the longest side to connect the upper and lower electrodes may obtain the smallest electrode led-in and led-out impedance. The first opening and the second opening may be disposed on two opposite shortest sides, such that the disturbance to the bulk acoustic wave caused by microstructure sudden change may be minimized, thereby not only suppressing impedance decrease, but also reducing quality factor loss.

Furthermore, the shape of the effective resonance region may use the hexagon (especially the longest two sides are approximately in parallel with each other). In such way, it may achieve consistency with spatial geometric continuation of the lattice of aluminum nitride or other piezoelectric crystal materials with a hexagonal lattice structure, because these piezoelectric crystals have exactly a hexagonal lattice shape along the horizontal direction. Meanwhile, the C axis of the hexagonal lattice may be kept nearly perpendicular to the plane of the piezoelectric layer, and the upper and lower surfaces of the piezoelectric layer may be kept in parallel with each other and nearly perpendicular to the C axis in such solution, which may be beneficial for achieving the best longitudinal piezoelectric induction and corresponding bulk acoustic wave characteristics.

Furthermore, when the piezoelectric material of hexagonal lattice is used, and three pairs of opposite sides of the hexagon in the effective resonance region are in parallel with each other, the interior angles are all 120 degrees, and the opposite sides which are in parallel with each other are unequal in length, the resonator may have desirable impedance Zp and quality factor Qp. The lattice of the piezoelectric layer material is a hexagonal lattice, the atoms are arranged in a regular hexagon, and the six apex angles are all 120 degrees. Due to the integrity of the unit cell, the lattice vibration is based on the unit cell. If a part of the unit cell is outside the working region, a part of the mechanical vibration energy may inevitably be lost outside the working region. When the working region of the resonator is also designed as a hexagon with an apex angle of 120 degrees, such design may best fit the shape of the lattice, and the most complete lattices in the working region may be included. In such case, only the fewest unit cells may cross the boundary of the working region, thereby reducing the energy loss of mechanical vibration.

Furthermore, through analyzing a large quantity of simulation data, the phenomenon that is different from conventional knowledge in the industry had been found, that is, when the opposite sides of the hexagon are in parallel with each other, the impedance Zp and quality factor Qp of the bulk acoustic resonator may be desirable. Moreover, compared with irregular polygonal effective resonance region in the existing technology, in one solution, the hexagonal resonance region with some or all opposite sides in parallel with each other may have a regular shape, which may solve the problems of optical alignment, online device size measurement and the like existing in irregular patterns in the fabrication process, and may provide more convenience for process processing and online inspection.

In addition, by analyzing the lattice structure of the piezoelectric material, it had been found that the impedance Zp and the quality factor Qp of the bulk acoustic resonator may be desirable when the number of sides of the crystal plane of the lattice structure is also six. When the number of sides of the crystal plane of the lattice structure is six, and when the shape of the hexagon is substantially coincident with the hexagon shape of the effective resonance region (the interior angles corresponding to two hexagons are substantially equal to each other), the impedance Zp and quality factor Qp of the bulk acoustic resonator may be desirable.

Furthermore, it had been found through simulation that when the length of the first side adjacent to the first side and the third side is greater than 1.25 times the length of the third side, the quality factor of the resonator may be relatively high.

Above-mentioned description may be merely for the description of preferred embodiments of the present disclosure and may not be intended to limit the scope of the present disclosure. Any changes and modifications based on above-mentioned embodiments made by those skilled in the art may all be within the scope of the present disclosure.

What is claimed is:

1. A film piezoelectric acoustic resonator, comprising:
an upper electrode, a piezoelectric layer and a lower electrode which are stacked sequentially from a top to a bottom, wherein:
in an effective resonance region, the upper electrode, the piezoelectric layer and the lower electrode are sequentially overlapped with each other, and a projection of the effective resonance region along a direction of the piezoelectric layer is a hexagon;
the hexagon has a first side with a longest length, a second side opposite to the first side, a third side with a shortest length, and a fourth side opposite to the third side;
a portion of the upper electrode extending out of the effective resonance region through a first boundary of the effective resonance region is defined as an upper electrode led-out portion; a portion of the lower electrode extending out of the effective resonance region through a second boundary of the effective resonance region is defined as a lower electrode led-out portion; and one of the first boundary and the second boundary is the first side, and the other one of the first boundary and the second boundary is the second side;
a first external signal connection terminal is connected to the upper electrode led-out portion, and a second external signal connection terminal is connected to the lower electrode led-out portion;
a first opening at the third side passes through the upper electrode, the piezoelectric layer and the lower electrode outside the effective resonance region; and
a second opening at the fourth side passes through the upper electrode, the piezoelectric layer and the lower electrode outside the effective resonance region.

2. The film piezoelectric acoustic resonator according to claim 1, wherein:
a material of the piezoelectric layer has a lattice structure having a hexagonal crystal plane.

3. The film piezoelectric acoustic resonator according to claim 2, wherein:
each interior angle of the hexagonal crystal plane is substantially same as each interior angle of the hexagonal effective resonance region; and/or
the material of the piezoelectric layer has the hexagonal lattice structure.

4. The film piezoelectric acoustic resonator according to claim 3, wherein:
a maximum interior angle of the hexagon is equal to or less than 140 degrees, and a minimum interior angle of the hexagon is equal to or more than 100 degrees; and/or
three pairs of opposite sides of the hexagon are in parallel or approximately in parallel with each other, and all interior angles are 120 degrees; and the opposite sides of the hexagon which are in parallel or approximately in parallel with each other are unequal in length; and/or
the piezoelectric layer is made of a material including aluminum nitride, wherein a C axis of the piezoelectric layer is approximately perpendicular to a plane of the piezoelectric layer.

5. The film piezoelectric acoustic resonator according to claim 4, wherein:
upper and lower surfaces of the piezoelectric layer are maintained to be in parallel with each other and perpendicular to the C axis.

6. The film piezoelectric acoustic resonator according to claim 1, wherein:
the hexagon includes at least a pair of opposite sides which are in parallel or approximately in parallel with each other; and the opposite sides which are in parallel or approximately in parallel with each other are equal or unequal in length.

7. The film piezoelectric acoustic resonator according to claim 6, wherein:
the first side and the second side are opposite sides which are in parallel or approximately in parallel with each other.

8. The film piezoelectric acoustic resonator according to claim 7, wherein:
the first side and the second side are unequal in length; and/or
the second side is a second longest side of the hexagon; and/or
the third side and the fourth side are opposite sides which are in parallel or approximately in parallel with each other.

9. The film piezoelectric acoustic resonator according to claim 8, wherein:
the fourth side is a second shortest side of the hexagon.

10. The film piezoelectric acoustic resonator according to claim 1, wherein:
the first side is adjacent to the third side; and a ratio of a length of the first side to a length of the third side is greater than 1.25.

11. The film piezoelectric acoustic resonator according to claim 1, wherein:
the first opening is disposed into the third side and perpendicular to a length direction of the third side or disposed into an end of the third side at an angle of the hexagon; and/or
the second opening is disposed into the fourth side and perpendicular to a length direction of the fourth side or disposed into an end of the fourth side at an angle of the hexagon.

12. The film piezoelectric acoustic resonator according to claim 1, wherein:
a first trench passing through the upper electrode is formed in the upper electrode, and a second trench passing through the lower electrode is formed in the lower electrode;
the first trench is on an opposite side of the upper electrode led-out portion, and the second trench is on an opposite side of the lower electrode led-out portion; and
each of the first trench and the second trench is a part of a boundary of the effective resonance region.

13. The film piezoelectric acoustic resonator according to claim 1, wherein:
the piezoelectric layer is a complete piezoelectric layer; or the piezoelectric layer has a trench which is a part of a boundary of the effective resonance region.

14. The film piezoelectric acoustic resonator according to claim 12, wherein:
each of the first trench and the second trench is in a partial-ring shape; and the first opening and the second opening are formed at two junctions of the first trench and the second trench.

15. The film piezoelectric acoustic resonator according to claim 12, wherein:
the first trench is in a partial-ring shape, and the first trench is disposed opposite to the upper electrode led-out portion; and/or
the second trench is in a partial-ring shape, and the second trench is disposed opposite to the lower electrode led-out portion.

16. The film piezoelectric acoustic resonator according to claim 14, wherein:
a bottom surface of the first trench is on an upper surface or a lower surface of the piezoelectric layer or in a middle of the piezoelectric layer; and/or
a bottom surface of the second trench is on an upper surface or a lower surface of the piezoelectric layer or in a middle of the piezoelectric layer.

17. The film piezoelectric acoustic resonator according to claim 1, further including:
a carrier substrate including an acoustic reflection structure, wherein the effective resonance region is above a region enclosed by the acoustic reflection structure.

18. The film piezoelectric acoustic resonator according to claim 17, wherein:
the acoustic reflection structure includes a first cavity or a Bragg acoustic reflection layer; and/or
the carrier substrate includes a first substrate and a support layer bonded to the first substrate; and the support layer is formed with a first cavity passing through the support layer.

19. A filter, comprising:
a film piezoelectric acoustic resonator, comprising:
an upper electrode, a piezoelectric layer and a lower electrode which are stacked sequentially from a top to a bottom, wherein:
in an effective resonance region, the upper electrode, the piezoelectric layer and the lower electrode are sequentially overlapped with each other, and a projection of the effective resonance region along a direction of the piezoelectric layer is a hexagon;
the hexagon has a first side with a longest length, a second side opposite to the first side, a third side with a shortest length, and a fourth side opposite to the third side;
a portion of the upper electrode extending out of the effective resonance region through a first boundary of the effective resonance region is defined as an upper electrode led-out portion; a portion of the lower electrode extending out of the effective resonance region through a second boundary of the effective resonance region is defined as a lower electrode led-out portion; and one of the first boundary and the second boundary is the first side, and the other one of the first boundary and the second boundary is the second side;
a first external signal connection terminal is connected to the upper electrode led-out portion, and a second external signal connection terminal is connected to the lower electrode led-out portion;
a first opening at the third side passes through the upper electrode, the piezoelectric layer and the lower electrode outside the effective resonance region; and
a second opening at the fourth side passes through the upper electrode, the piezoelectric layer and the lower electrode outside the effective resonance region.

20. An electronic apparatus, comprising:
a filter, comprising:
a film piezoelectric acoustic resonator, comprising:
an upper electrode, a piezoelectric layer and a lower electrode which are stacked sequentially from a top to a bottom, wherein:
in an effective resonance region, the upper electrode, the piezoelectric layer and the lower electrode are sequentially overlapped with each other, and a projection of the effective resonance region along a direction of the piezoelectric layer is a hexagon;
the hexagon has a first side with a longest length, a second side opposite to the first side, a third side with a shortest length, and a fourth side opposite to the third side;
a portion of the upper electrode extending out of the effective resonance region through a first boundary of the effective resonance region is defined as an upper electrode led-out portion; a portion of the lower electrode extending out of the effective resonance region through a second boundary of the effective resonance region is defined as a lower electrode led-out portion; and one of the first boundary and the second boundary is the first side, and the other one of the first boundary and the second boundary is the second side;
a first external signal connection terminal is connected to the upper electrode led-out portion, and a second external signal connection terminal is connected to the lower electrode led-out portion;
a first opening at the third side passes through the upper electrode, the piezoelectric layer and the lower electrode outside the effective resonance region; and
a second opening at the fourth side passes through the upper electrode, the piezoelectric layer and the lower electrode outside the effective resonance region.
